(19) United States
(12) Patent Application Publication
(10) Pub. No.: US 2017/0126192 A1
(43) Pub. Date: May 4, 2017

(54) METHOD, DEVICE, AND COMPUTER-READABLE MEDIUM FOR ADJUSTING VOLUME

(71) Applicant: Xiaomi Inc., Beijing (CN)

(72) Inventors: Qiang FU, Beijing (CN); Shiquan ZHOU, Beijing (CN); Enxing HOU, Beijing (CN)

(73) Assignee: Xiaomi Inc., Beijing (CN)

(21) Appl. No.: 15/297,712

(22) Filed: Oct. 19, 2016

(30) Foreign Application Priority Data
Oct. 29, 2015 (CN) 201510717388.1

(51) Int. Cl. H03G 3/32; H04R 3/00; H04R 29/00

(52) U.S. Cl. CPC H03G 3/32; H04R 29/001; H04R 3/00

(57) ABSTRACT

Methods, devices, and computer-readable media for adjusting volume are provided in the disclosure. A method for adjusting volume may include acquiring, with a device, ambient noise information about ambient noise present during playing of sound. The method may further include adjusting volume of the sound based on the acquired ambient noise information. By acquiring ambient noise information, the method may provide that volume of the sound is adjusted based on the acquired ambient noise information. Because the acquired ambient noise information may reflect the current ambient noise level, the method may adjust volume of the sound based on the acquired ambient noise information without requiring manual adjusting of volume by a user, which may be convenient to the user.

### CROSS-REFERENCE TO RELATED APPLICATION

This application is based on and claims priority to Chinese Patent Application No. 201510717388.1, filed Oct. 29, 2015, which is incorporated herein by reference in its entirety.

### FIELD

The present disclosure generally relates to the field of communication technology, and more particularly to methods, devices, terminals, and computer-readable media for adjusting volume.

### BACKGROUND

With rapid development of terminal technology, there are increasing numbers of media player devices such as smart radios, BLUETOOTH speakers, or the like. When using media player devices, users generally need to adjust the volume manually if ambient noise changes, which may be inconvenient for users.

### SUMMARY

In view of related art, methods and devices for adjusting volume are provided in this disclosure.

According to a first aspect of embodiments of the present disclosure, a method for adjusting volume is provided. The method may include acquiring, with a device, ambient noise information about ambient noise present during playing of sound. The method may further include adjusting, with the device, volume of the sound based on the acquired ambient noise information.

According to a second aspect of embodiments of the present disclosure, a device for adjusting volume is provided. The device may include a processor and a memory for storing processor-executable instructions. The processor may be configured to acquire ambient noise information about ambient noise present during playing of sound. The processor may be further configured to adjust volume of the sound based on the acquired ambient noise information.

According to a third aspect of the present disclosure, there is provided a non-transitory computer-readable storage medium having stored therein instructions to perform a method for adjusting volume. The instructions may be configured to, when executed by a processor of a mobile terminal, cause the mobile terminal to acquire ambient noise information about ambient noise present during playing of sound. The instructions may be configured to, when executed by a processor of a mobile terminal, cause the mobile terminal to adjust volume of the sound based on the acquired ambient noise information.

Both the forgoing general description and the following detailed description are exemplary only, and are not restrictive of the present disclosure.

### BRIEF DESCRIPTION OF THE DRAWINGS

The accompanying drawings, which are incorporated in and constitute a part of this specification, illustrate embodiments consistent with the disclosure and, together with the description, serve to explain principles of the disclosure.

FIG. 1 is a flow chart illustrating a method for adjusting volume according to an exemplary embodiment.

FIG. 2 is a flow chart illustrating a method for adjusting volume according to an exemplary embodiment.

FIG. 3 is a flow chart illustrating a method for adjusting volume according to an exemplary embodiment.

FIG. 4 is a flow chart illustrating a method for adjusting volume according to an exemplary embodiment.

FIG. 5 is a schematic diagram illustrating an application environment in which to apply a method for adjusting volume according to an exemplary embodiment.

FIG. 6 is a block diagram illustrating a device for adjusting volume according to an exemplary embodiment.

FIGS. 7-12 are block diagrams illustrating a device for adjusting volume according to an exemplary embodiment.

FIG. 13 is a block diagram illustrating a device for adjusting volume according to an exemplary embodiment.

### DETAILED DESCRIPTION

Reference will now be made in detail to exemplary embodiments, examples of which are illustrated in the accompanying drawings. The following description refers to the accompanying drawings, in which the same numbers in different drawings represent same or similar elements unless otherwise described. The implementations set forth in the following description of exemplary embodiments do not represent all implementations consistent with the disclosure. Instead, they are merely examples of devices and methods consistent with aspects related to the disclosure and the appended claims.

The terms used in the present disclosure are merely for describing particular embodiments rather than limiting the present disclosure. Terms, such as “a”, “an”, “said”, and “the”, as used in singular form in the present disclosure and appended claims may include plural form, unless otherwise described. The term “and/or” used herein may refer to and include any or all of possible combinations of one or more associated items which have been listed.

The terms “first,” “second,” and “third,” may be used to describe concepts, but these concepts are not limited by these terms. These terms may, for example, be used only to distinguish a number of instances of the same type of concept from each other. For example, the “first concept” may also be referred as the “second concept” without departing from the scope of the present disclosure. Similarly, the “second concept” may also be referred as the “first concept.” The word “if” as used herein may be interpreted as “when” or “while” or “in response to a determination that” depending on the context.

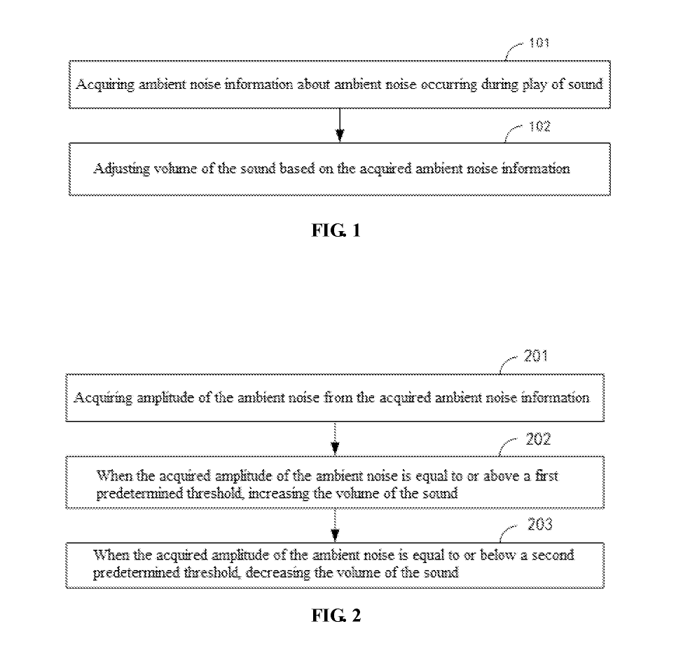

FIG. 1 is a flow chart illustrating a method for adjusting volume according to an exemplary embodiment. A method may include the following steps 101-102.

In step 101, ambient noise information about noise present during playing of sound may be acquired during the playing of the sound.

In step 102, volume of the sound may be adjusted based on the acquired ambient noise information.

In embodiments of the present disclosure, by acquiring ambient noise information, i.e. noise information about ambient noise present while sound is playing, volume of the sound may be adjusted based on the acquired noise information. Because the acquired ambient noise information may reflect the current condition of ambient noise where the sound is being played, volume of the sound may be adjusted based on the acquired noise information without requiring manual adjustment of the volume by a user, which may be convenient for the user.

Embodiments of the present disclosure may be performed by a media player device configured to play at least one type of media, such as audio signals, video signals, animation, or the like. The media player device may be, for example, a computer, tablet computer, television, mobile phone, personal stereo, handheld reader, or the like. Embodiments of the present disclosure may be performed by a control device configured to control the playing of media by a media player device. The media player device may have a media playing control function, and may have both a media playing control function and a noise capture function. The control device may have a noise capture function.

In step 101, an ambient noise signal may generally be captured by capturing or recording ambient noise around a terminal. An ambient noise signal may include various noise parameters, such as tone, volume, timbre, or the like. In embodiments of the present disclosure, ambient noise information may refer to volume of ambient noise. Volume may be known as loudness (or the loudness of a sound), represent the strength of a sound, and have a unit of “decibels (dB)”. Playing sound may include any manner of outputting an audio signal with a terminal, such as outputting sound when a smart terminal is playing an audio file or when a smart terminal is playing a video file, outputting sound when a mobile phone is communicating with another different terminal via telephonic communication such as during a telephone call, outputting sound with a wireless speaker after receiving an audio signal from a control device, or outputting sound with a smart radio after the smart radio receives a radio wave and converts it into an audio signal.

In an implementation, a manner of acquiring ambient noise information may include detecting the ambient noise information with a built-in noise capture sensor, such as a microphone or a decibel meter. A noise capture sensor may be built into a device configured to execute embodiments of the present disclosure, such as a media player device or a control device described above. The captured ambient noise information may be a direct measurement of amplitude of the ambient noise, or may be a detection of amplitude of the ambient noise derived from the captured ambient noise information.

In an additional or alternative implementation, a manner of acquiring ambient noise information may include receiving ambient noise information sent from a noise capture device. A noise capture device may be separate from the device configured to execute embodiments of the present disclosure. The captured ambient noise information may be a direct measurement of amplitude of the ambient noise, such as a read-out from a decibel meter, or may be a detection of amplitude of the ambient noise derived from the captured ambient noise information.

In step 102, a predetermined corresponding relationship may be established between different kinds or values of ambient noise information and various corresponding volume adjustments. Volume adjustment corresponding to the acquired ambient noise information may be performed based on the predetermined corresponding relationship. The volume adjustment may refer to adjustment of a common volume for sound output involved in audio, video, telephone calls, or the like, for example, by increasing (or “turning up”) the volume or decreasing (or “turning down”) the volume device. For example, the volume of the sound may be increased when the ambient environment is detected to be noisy based on acquired ambient noise information, or the volume of the sound may be decreased when the ambient noise is detected to decrease.

In an implementation, adjusting volume of the sound based on the acquired ambient noise information may include, when the sound is playing on a terminal executing the method, directly adjusting the volume of the sound playing on the terminal, based on the acquired ambient noise information. In an additional or alternative implementation, adjusting the volume of the sound based on the acquired ambient noise information may include, when the sound is playing on another different terminal, generating a control instruction configured to adjust the volume of the sound based on the acquired ambient noise information, and sending the control instruction to the other terminal to trigger the other terminal to adjust the volume of the sound playing on the other terminal, based on the acquired ambient noise information.

In embodiments of the present disclosure, in a common application scenario, a method for adjusting volume may be performed by a media player. For example, a media player device may directly adjust volume of the media player device when the sound is played on the media player device. In another common application scenario, a method for adjusting volume may be performed by a control device configured to control the media playing of the media player device. For example, as the sound is played on a media player device, a control device may generate a control instruction and send it to the media player device to trigger the media player device to adjust volume of the media player device accordingly. In other application scenarios, a method for adjusting volume may be performed by a control device configured to control the media playing of the media player device. For example, a control device may output sound and a media player device may also output sound at a same time. The control device may directly adjust volume of the sound which is currently being played on the control device based on the acquired ambient noise information, and at the same time may also generate a control instruction and send it to the media player device to trigger the media player device to adjust volume of the media player device accordingly. In manners described above, volume of the sound on a presently operated terminal may be adjusted, and volume of the sound on another different terminal may independently or simultaneously adjusted, which may improve flexibility and effectiveness of adjusting volume.

In above embodiments of the present disclosure, by acquiring ambient noise information, volume of the sound may be adjusted based on the acquired ambient noise information. Because the acquired ambient noise information may reflect the condition of current ambient noise, volume of the sound may be adjusted based on the acquired ambient noise information without requiring manual adjustment of the volume by a user, which may be convenient for the user.

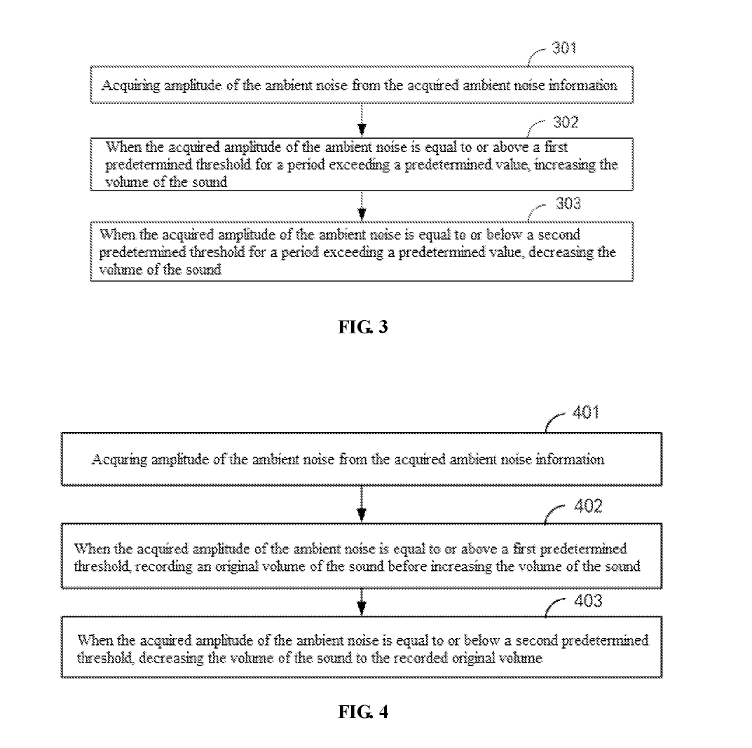

FIG. 2 is a flow chart illustrating a method for adjusting volume according to an exemplary embodiment. In accordance with above embodiments shown in FIG. 1, present embodiments describe a processing procedure by which volume of the sound may be adjusted based on the acquired ambient noise information. The procedure may include the following steps 201-203.

In step 201, amplitude of the ambient noise may be acquired from the acquired ambient noise information.

In step 202, the volume of the sound may be increased when the acquired amplitude of the ambient noise is determined to be equal to or above a first predetermined threshold.

In step 203, the volume of the sound may be decreased when the acquired amplitude of the ambient noise is determined to be equal to or below a second predetermined threshold.

In embodiments of the present disclosure, amplitude of the ambient noise may be acquired from the acquired ambient noise information, and the level of the ambient noise may be determined based on the acquired amplitude of the ambient noise. When the amplitude of the ambient noise is large, the ambient noise may be determined to be large, and when the amplitude of the ambient noise is low, the ambient noise may be determined to be low. Exemplary first predetermined threshold values or second predetermined threshold values may be values such as 50 dB, 60 dB, or the like, but those skilled in the art may configure the value of the threshold as desired, and the disclosure is not limited to these exemplary embodiments. When the amplitude of the ambient noise is large (i.e. exceeds the first predetermined threshold), the ambient environment is noisy, and thus the current volume of the sound may be increased automatically so as to improve the effect of playing sound. When the amplitude of the ambient noise changes from high to low, the current volume of the sound may be decreased automatically so as to improve the effect of playing sound. Such an implementation may easily improve the efficiency of adjusting volume.

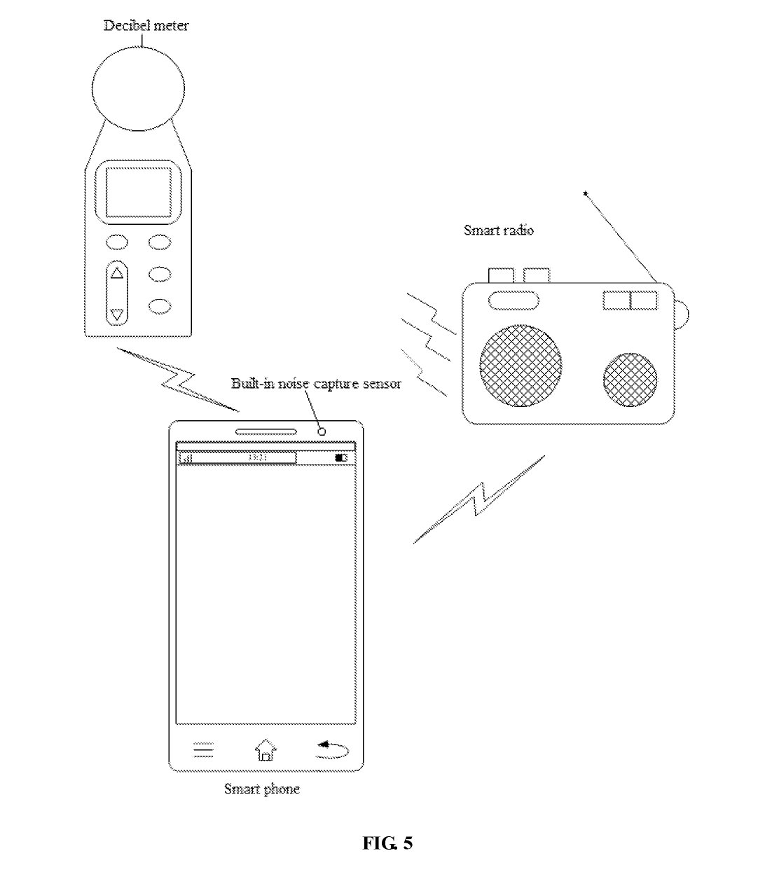

FIG. 3 is a flow chart illustrating a method for adjusting volume according to an exemplary embodiment. In accordance with the above embodiments shown in FIG. 1, present embodiments describe a processing procedure by which volume of the sound may be adjusted based on the acquired ambient noise information. The procedure may include the following steps 301-303.

In step 301, amplitude of the ambient noise may be acquired from the acquired ambient noise information.

In step 302, the volume of the sound may be increased when the acquired amplitude of the ambient noise is determined to be equal to or above a first predetermined threshold for a period exceeding a predetermined value.

In step 303, the volume of the sound may be decreased when the acquired amplitude of the ambient noise is determined to be equal to or below a second predetermined threshold for a period exceeding a predetermined value.

In embodiments of the present disclosure, amplitude of the ambient noise may be acquired from the acquired ambient noise information, and the level of ambient noise may be determined based on the acquired amplitude of the ambient noise, for example by comparing the acquired ambient noise information to a predetermined threshold. When the amplitude of the ambient noise is large, the ambient noise may be determined to be large, and when the amplitude of the ambient noise is low, the ambient noise may be determined to be low. Exemplary first predetermined threshold values or second predetermined threshold values may be values such as 50 dB, 60 dB, or the like, and an exemplary value for a predetermined value may be an amount of time, such as 5 seconds, 10 seconds or the like, but those skilled in the art may configure the values of the threshold or the predetermined value as desired, and the present disclosure is not limited to these exemplary embodiments. When the amplitude of the ambient noise is large (i.e. exceeds the first predetermined threshold) for a period exceeding a predetermined amount of time, the ambient environment is noisy, and thus the current volume of the sound may be increased automatically so as to improve the effect of playing sound. When the amplitude of the ambient noise changes from high to low and is below the second predetermined threshold for a period exceeding a predetermined amount of time, the current volume of the sound may be decreased automatically so as to improve the effect of playing sound. Such an implementation may easily improve efficiency of adjusting volume.

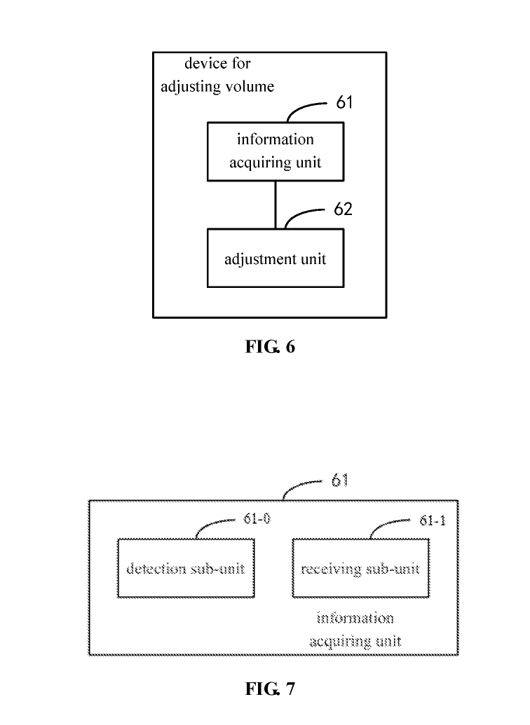

FIG. 4 is a flow chart illustrating a method for adjusting volume according to an exemplary embodiment. In accordance with the above embodiments shown in FIG. 1, present embodiments describe a processing procedure by which volume of the sound may be adjusted based on the acquired ambient noise information. The procedure may include the following steps 401-403.

In step 401, amplitude of the ambient noise may be acquired from the acquired ambient noise information.

In step 402, when the acquired amplitude of the ambient noise is determined to be equal to or above a first predetermined threshold, an original volume of the sound may be recorded, and after the original volume of the sound is recorded, the volume of the sound may be increased.

In step 403, when the acquired amplitude of the ambient noise is determined to be equal to or below a second predetermined threshold, the volume of the sound may be decreased to the recorded original volume of the sound.

In embodiments of the present disclosure, amplitude of the ambient noise may be acquired from the acquired ambient noise information, and the level of ambient noise may be determined based on the acquired amplitude of the ambient noise, for example by comparing the acquired ambient noise information to a predetermined threshold. When the amplitude of the ambient noise is large, the ambient noise may be determined to be large, and when the amplitude of the ambient noise is low, the ambient noise may be determined to be low. Exemplary first predetermined threshold values or second predetermined threshold values may be values such as 50 dB, 60 dB, or the like, but those skilled in the art may configure the value of the threshold as desired, and the present disclosure is not limited to these exemplary embodiments. The original volume may refer to a volume set by a user before the volume of the sound is adjusted based on the acquired amplitude of the ambient noise. After increasing the volume of the sound based on the acquired amplitude of the ambient noise, the volume of the sound may be decreased to the original volume of the sound when the amplitude of the ambient noise is detected to decrease, so as to make the volume of the sound return to a volume set by a user. Such an implementation may make the volume adjustment more flexible, and may improve the effect of adjusting volume.

In implementations, adjusting the volume of the sound based on the acquired ambient noise information may include acquiring an amplitude of the ambient noise from the acquired ambient noise information. It may further include acquiring a volume adjustment parameter corresponding to the acquired amplitude of the ambient noise. It may further include adjusting the volume of the sound based on the acquired volume adjustment parameter.

In embodiments of the present disclosure, a predetermined corresponding relationship may be established between different amplitudes of ambient noise and corresponding volume adjustment parameters, for example by being stored or set in a manner accessible to the device, for example by a manufacturer of the device, by the user, or through updates received by the device. Because different amplitudes of ambient noise may correspond to different respective volume adjustment parameters, more precise adjustment may be made when increasing volume of a sound, so as to improve the effect of playing sound. A volume adjustment parameter may be a specific volume adjustment value, for example an increase or decrease of volume by 10 dB, an increase or decrease of volume by 20 dB, or the like. A volume adjustment parameter may be a volume adjustment ratio, for example an increase or decrease of volume by 5%, an increase or decrease of volume by 10%, or the like. For example, when the amplitude of the ambient noise ranges from 80 dB to 90 dB, the corresponding volume adjustment parameter may be to increase the volume by 10 dB, or increase the volume by 5%, or the like. And when the amplitude of the ambient noise ranges from 30 dB to 40 dB, the corresponding volume adjustment parameter may be to decrease the volume by 10 dB, or decrease the volume by 5%, or the like. In practice, those skilled in the art may configure the volume adjustment parameter as desired, and may configure the corresponding relationship between different amplitudes of ambient noise and respective volume adjustment parameters as desired, and the disclosure is not limited to these exemplary embodiments.

In above embodiments of the present disclosure, by acquiring a volume adjustment parameter corresponding to the acquired amplitude of the ambient noise, volume of the sound may be adjusted based on the acquired volume adjustment parameter. Such an implementation may improve accuracy and effectiveness of adjusting volume, and may improve the effect of playing sound.

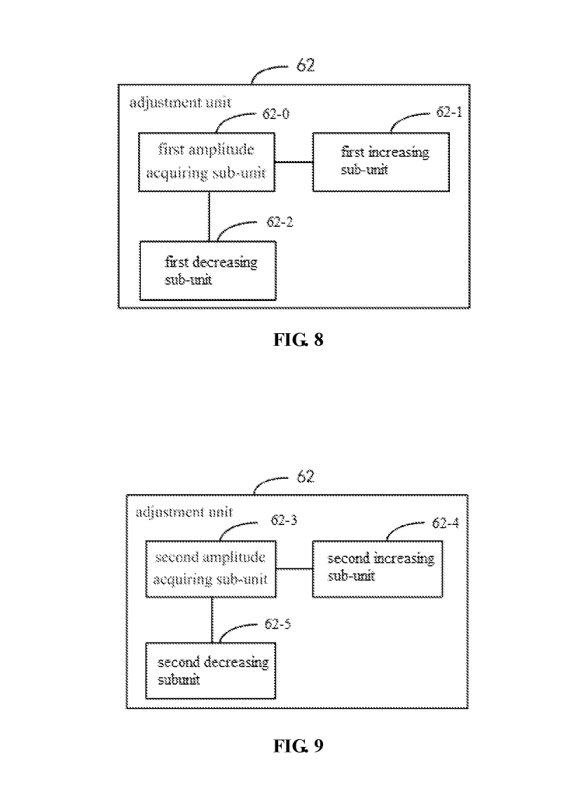

FIG. 5 is a schematic diagram illustrating an application environment in which to apply a method for adjusting volume according to an exemplary embodiment. The scenario shown in FIG. 5 may include a noise capture device embodied as a decibel meter, a control device embodied as a smart phone, and a media player device embodied as a smart radio. The decibel meter may in wireless connection with the smart phone, and information transmission and interaction may be conducted between the decibel meter and the smart phone through the wireless connection. The smart phone may in wireless connection with the radio, and information transmission and interaction may be conducted between the smart phone and the radio through the wireless connection. The decibel meter is only an example to illustrate a noise capture device of present embodiments. In practice, a noise capture device may, for example, be other terminals such as microphone, or the like. A noise capture device may be a noise capture sensor, such as a microphone, decibel meter, or the like that is built into a control device such as the smart phone, as shown in FIG. 5. A noise capture sensor may be of any shape or size, and be built into the smart phone at any location, as would be apparent to one of skill in the art, and accordingly is not limited to the illustrative depiction of FIG. 5. The smart phone is only an example to illustrate a control device of present embodiments. The smart radio is only an example to illustrate a media player device of present embodiments. In practice, a control device may, for example, be other smart terminals such as Personal Computer (PC), or the like. In practice, a media player device may, for example, be other digital broadcasting terminals such as a BLUETOOTH speaker, a DVD player, or the like.

In the application environment shown in FIG. 5, the decibel meter may detect amplitude of the ambient noise and send the detected amplitude of the ambient noise to the smart phone, as shown in FIG. 5. When the detected amplitude of the ambient noise is large, the smart phone may generate a corresponding control instruction configured to increase the volume based on the detected amplitude of the ambient noise, and send the control instruction to the smart radio. The smart radio may, in response to receipt of the control instruction from the smart phone, increase the volume in accordance with the ambient noise information.

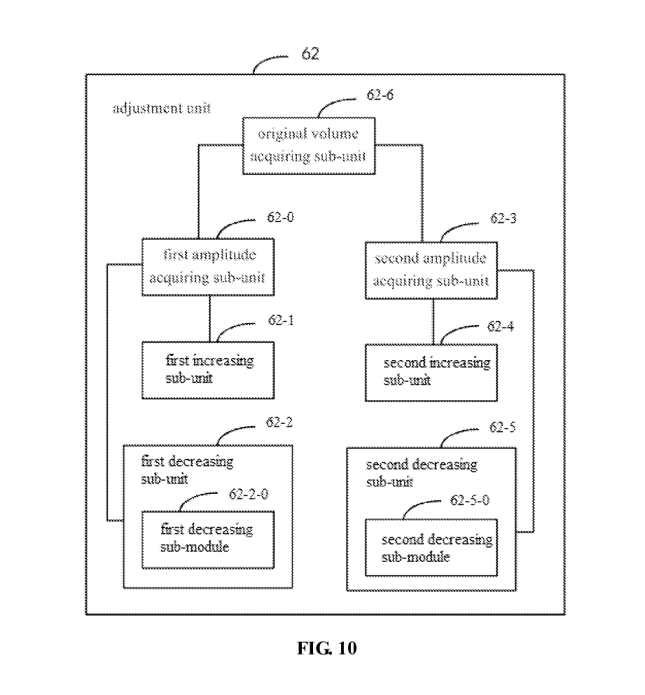

FIG. 6 is a block diagram illustrating a device for adjusting volume according to an exemplary embodiment. The device for adjusting volume may include: an information acquiring unit 61 and an adjustment unit 62. The information acquiring unit 61 may be configured to acquire ambient noise information about ambient noise present during playing of sound. The adjustment unit 62 may be configured to adjust volume of the sound based on the acquired ambient noise information.

In embodiments of the present disclosure, by acquiring ambient noise information, i.e. noise information about ambient noise present while sound is playing, the device may adjust volume of the sound based on the acquired noise information. Because the acquired ambient noise information may reflect the current condition of ambient noise where the sound is being played, the device may adjust volume of the sound based on the acquired noise information without requiring manual adjustment of the volume by a user, which may be convenient for the user.

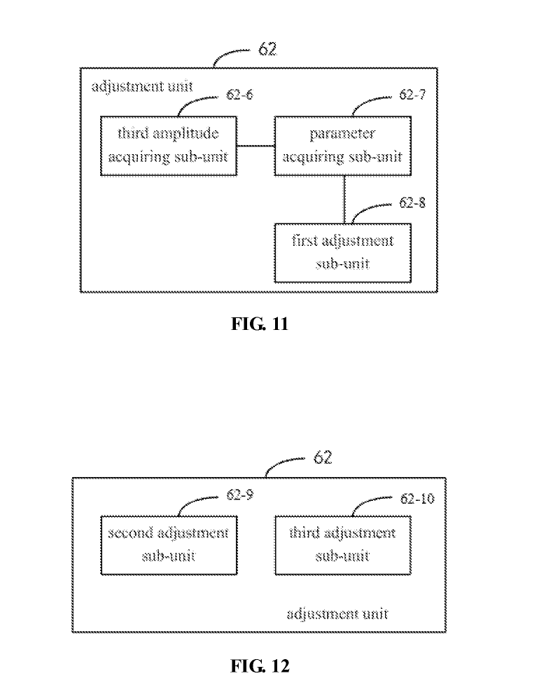

FIG. 7 is a block diagram illustrating a device for adjusting volume according to an exemplary embodiment. In accordance with the above embodiments shown in FIG. 6, the information acquiring unit 61 may include: a detection sub-unit 61-0, or a receiving sub-unit 61-1, or both. For convenience, the above two sub-units are show in FIG. 7 at the same time. The detection sub-unit 61-0 may be configured to detect the ambient noise information with a built-in noise capture sensor. A receiving sub-unit 61-1 may be configured to receive the ambient noise information from a noise capture device separate from the device for adjusting volume.

In embodiments of the present disclosure, the ambient noise information may be detected by a noise capture sensor built into the device for adjusting volume, or received by the device from a noise capture device separate from the device for adjusting volume. Such an implementation may easily increase the accuracy of the captured ambient noise information r.

FIG. 8 is a block diagram illustrating a device for adjusting volume according to an exemplary embodiment. In accordance with the above embodiments shown in FIG. 6, the adjustment unit 62 may include: a first amplitude acquiring sub-unit 62-0, a first increasing sub-unit 62-1, and a first decreasing sub-unit 62-2. The first amplitude acquiring sub-unit 62-0 may be configured to acquire amplitude of the ambient noise from the ambient noise information. The first increasing sub-unit 62-1 may be configured to increase the volume of the sound when the amplitude of the ambient noise is equal to or above a first predetermined threshold. The first decreasing sub-unit 62-2 may be configured to decrease the volume of the sound when the amplitude of the ambient noise is equal to or below a second predetermined threshold.

In embodiments of the present disclosure, by acquiring amplitude of the ambient noise from the acquired ambient noise information, the device may determine the manner of adjusting the volume based on a comparison by the device of the acquired amplitude of the ambient noise with a first predetermined threshold or a second predetermined threshold. Such an implementation may improve efficiency of adjusting volume.

FIG. 9 is a block diagram illustrating a device for adjusting volume according to an exemplary embodiment. In accordance with the above embodiments shown in FIG. 6, the adjustment unit 62 may include: a second amplitude acquiring sub-unit 62-3, a second increasing sub-unit 62-4, and a second decreasing sub-unit 62-5. The second amplitude acquiring sub-unit 62-3 may be configured to acquire amplitude of the ambient noise from the ambient noise information. The second increasing sub-unit 62-4 may be configured to increase the volume of the sound when the amplitude of the ambient noise is equal to or above a first predetermined threshold for a period exceeding a predetermined value. The second decreasing sub-unit 62-5 may be configured to decrease the volume of the sound when the amplitude of the ambient noise is equal to or below a second predetermined threshold for a period exceeding a predetermined value.

In embodiments of the present disclosure, by acquiring amplitude of the ambient noise from the ambient noise information, the device may increase the volume of the sound when the amplitude of the ambient noise exceeds a first predetermined threshold for a period exceeding a predetermined value, and the device may decrease the volume of the sound when the amplitude of the ambient noise is below a second predetermined threshold for a period exceeding a predetermined value. Such an implementation may easily improve efficiency of adjusting volume.

FIG. 10 is a block diagram illustrating another device for adjusting volume according to an exemplary embodiment. On the basis of the above embodiments shown in FIG. 8 and FIG. 9, the adjustment unit 62 may further include: an original volume acquiring sub-unit 62-6 configured to record original volume of the sound before the volume of the sound is increased before increasing the volume of the sound. Wherein, the first decreasing sub-unit 62-2 may include a first decreasing sub-module 62-2-0 configured to decrease the volume of the sound to the original volume of the sound. The second decreasing sub-unit 62-5 may include a second decreasing sub-module 62-5-0 configured to decrease the volume of the sound to the original volume of the sound.

In embodiments of the present disclosure, after increasing the volume of the sound based on the amplitude of the ambient noise, the device may decrease volume of the sound to the original volume of the sound when the amplitude of the ambient noise is detected to decrease, so as to make the volume of the sound return to a volume set by a user. Such an implementation may make the volume adjustment more flexible, and may improve the effect of adjusting volume.

FIG. 11 is a block diagram illustrating another device for adjusting volume according to an exemplary embodiment. In accordance with the above embodiments shown in FIG. 6, the adjustment unit 62 may include: a third amplitude acquiring sub-unit 62-6, a parameter acquiring sub-unit 62-7, and a first adjustment sub-unit 62-8. The third amplitude acquiring sub-unit 62-6 may be configured to acquire amplitude of the ambient noise from the acquired ambient noise information. The parameter acquiring sub-unit 62-7 may be configured to acquire a volume adjustment parameter corresponding to the acquired amplitude of the ambient noise. The first adjustment sub-unit 62-8 may be configured to adjust the volume of the sound based on the acquired volume adjustment parameter.

In embodiments of the present disclosure, by acquiring a volume adjustment parameter corresponding to the amplitude of the ambient noise, the device may adjust the volume of the sound based on the acquired volume adjustment parameter, which may improve accuracy and effectiveness of adjusting volume and improving the effect of playing sound.

FIG. 12 is a block diagram illustrating a device for adjusting volume according to an exemplary embodiment. In accordance with the above embodiments shown in FIG. 6, the adjustment unit 62 may include: a second adjustment sub-unit 62-9 or a third adjustment sub-unit 62-10, or both. For convenience, the above two sub-units are show in FIG. 12 at the same time. The second adjustment sub-unit 62-9 may be configured to, when the sound is playing on the device, directly adjust the volume of the sound playing on the device based on the acquired ambient noise information. Third adjustment sub-unit 62-10 may be configured to, when the sound is playing on another different device, generate a control instruction configured to adjust the volume of the sound based on the acquired ambient noise information and send the generated control instruction to the other different device to trigger the other different device to adjust the volume of the sound playing on the other device based on the ambient noise information.

In embodiments of the present disclosure, the device may adjust volume of the sound on the device executing the method, and the device may also adjust volume of the sound on another different device, which may improve flexibility and effectiveness of adjusting volume.

Accordingly, a device, which may be a terminal, is provided in the present disclosure, and may include a processor and a memory for storing processor-executable instructions. The processor may be configured to acquire ambient noise information present during playing of sound and adjust volume of the sound based on the acquired ambient noise information.

The processes of implementing the functions of respective modules in the above device may be similar or identical to the corresponding steps described in the above methods, and will not be elaborated herein.

For embodiments of the device, because they operate in a manner corresponding to embodiments of the method, reference can be made to the description in embodiments of the method for purposes of implementation. The embodiments of the devices described above are only illustrative. A unit described as being a separate component may or may not be separate physically. A component shown as a unit may or may not be a single physical unit. For example, the component may be located in a single place or may be distributed over a plurality of network units. Use of part or all of the modules can be selected according to actual demand, so as to achieve goals of the solutions of the present disclosure. A person of ordinary skill in the art can appreciate and practice the disclosed embodiments and other apparent embodiments without creative work.

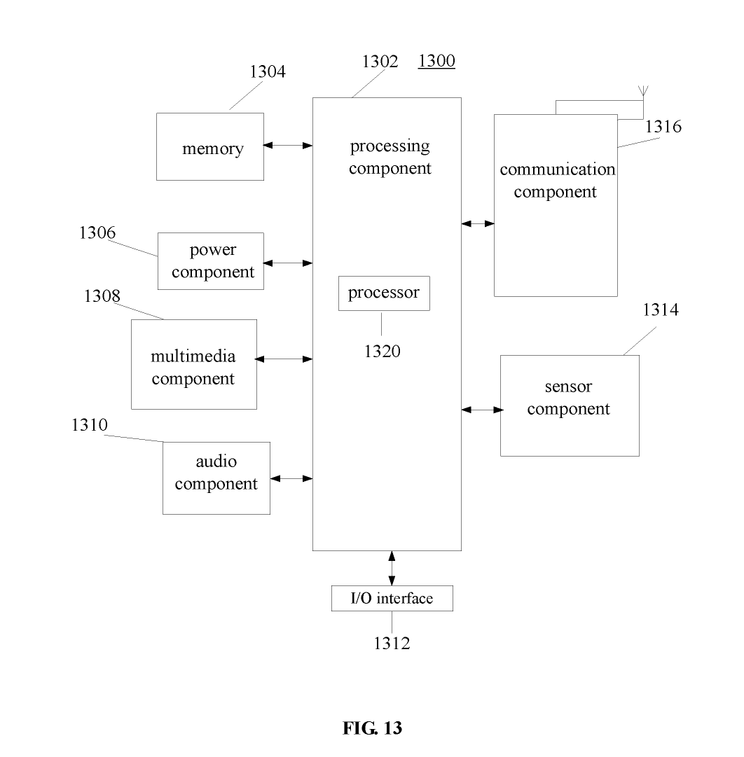

FIG. 13 is a block diagram of an device 1300 for adjusting volume according to an exemplary embodiment. For example, the device 1300 may be a mobile phone, a computer, a digital broadcast terminal, a messaging device, a gaming console, a tablet, a medical device, exercise equipment, a personal digital assistant, and the like.

Referring to FIG. 13, the device 1300 may include one or more of the following components: a processing component 1302, a memory 1304, a power component 1306, a multimedia component 1308, an audio component 1310, an input/output (I/O) interface 1312, a sensor component 1314, and a communication component 1316.

The processing component 1302 typically controls overall operations of the device 1300, such as the operations associated with display, telephone calls, data communications, camera operations, and recording operations. The processing component 1302 may include one or more processors 1320 to execute instructions to perform all or part of the steps in the above described methods. Moreover, the processing component 1302 may include one or more modules which facilitate the interaction between the processing component 1302 and other components. For instance, the processing component 1302 may include a multimedia module to facilitate the interaction between the multimedia component 1308 and the processing component 1302. Processing component 1302 may include any or all of the units, sub-units, modules, or sub-modules described above, such as the information acquiring unit 61, adjustment unit 62, detection sub-unit 61-0, receiving sub-unit 61-1, first amplitude acquiring sub-unit 62-0, first increasing sub-unit 62-1, first decreasing sub-unit 62-2, second amplitude acquiring sub-unit 62-3, second increasing sub-unit 62-4, second decreasing sub-unit 62-5, original volume acquiring sub-unit 62-6, first decreasing sub-module 62-2-0, second decreasing sub-module 62-5-0, third amplitude acquiring sub-unit 62-4, parameter acquiring sub-unit 62-7, first adjustment sub-unit 62-8, second adjustment sub-unit 62-9, and third adjustment sub-unit 62-10.

Each module discussed above, such as the information acquiring unit 61, adjustment unit 62, detection sub-unit 61-0, receiving sub-unit 61-1, first amplitude acquiring sub-unit 62-0, first increasing sub-unit 62-1, first decreasing sub-unit 62-2, second amplitude acquiring sub-unit 62-3, second increasing sub-unit 62-4, second decreasing sub-unit 62-5, original volume acquiring sub-unit 62-6, first decreasing sub-module 62-2-0, second decreasing sub-module 62-5-0, third amplitude acquiring sub-unit 62-4, parameter acquiring sub-unit 62-7, first adjustment sub-unit 62-8, second adjustment sub-unit 62-9, and third adjustment sub-unit 62-10, may take the form of a packaged functional hardware unit designed for use with other components, a portion of a program code (e.g., software or firmware) executable by the processor 1320 or the processing circuitry that usually performs a particular function of related functions, or a self-contained hardware or software component that interfaces with a larger system, for example.

The memory 1304 is configured to store various types of data to support the operation of the device 1300. Examples of such data include instructions for any applications or methods operated on the device 1300, contact data, phonebook data, messages, pictures, video, etc. The memory 1304 may be implemented using any type of volatile or non-volatile memory devices, or a combination thereof, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic or optical disk.

The power component 1306 provides power to various components of the device 1300. The power component 1306 may include a power management system, one or more power sources, and any other components associated with the generation, management, and distribution of power for the device 1300.

The multimedia component 1308 includes a screen providing an output interface between the device 1300 and the user. In some embodiments, the screen may include a liquid crystal display (LCD) and a touch panel (TP). If the screen includes the touch panel, the screen may be implemented as a touch screen to receive input signals from the user. The touch panel includes one or more touch sensors to sense touches, swipes, and gestures on the touch panel. The touch sensors may not only sense a boundary of a touch or swipe action, but also sense a period of time and a pressure associated with the touch or swipe action. In some embodiments, the multimedia component 1308 includes a front camera and/or a rear camera. The front camera and the rear camera may receive an external multimedia datum while the device 1300 is in an operation mode, such as a photographing mode or a video mode. Each of the front camera and the rear camera may be a fixed optical lens system or have optical focusing and zooming capability.

The audio component 1310 is configured to output and/or input sounds. For example, the audio component 1310 includes a microphone (“MIC”) configured to receive an external sound when the device 1300 is in an operation mode, such as a call mode, a recording mode, and a voice recognition mode. Audio component 1310 may, for example, include a microphone, decible meter, or other sensor that is configured to serve as a noise capture sensor as described in this disclosure. The received sound may be converted to an audio signal and further stored in the memory 1304, for example as ambient noise information described in this disclosure, or transmitted via the communication component 1316. The stored or transmitted audio signal may be accessible as ambient noise information to one or more units, sub-units, or sub-modules configured to process ambient noise information according to this disclosure. In some embodiments, the audio component 1310 further includes a speaker to output sounds.

The I/O interface 1312 provides an interface between the processing component 1302 and peripheral interface modules, the peripheral interface modules being, for example, a keyboard, a click wheel, buttons, and the like. The buttons may include, but are not limited to, a home button, a volume button, a starting button, and a locking button.

The sensor component 1314 includes one or more sensors to provide status assessments of various aspects of the device 1300. For instance, sensor component 1314 may detect an open/closed status of the device 1300, relative positioning of components (e.g., the display and the keypad, of the device 1300), a change in position of the device 1300 or a component of the device 1300, a presence or absence of user contact with the device 1300, an orientation or an acceleration/deceleration of the device 1300, and a change in temperature of the device 1300. The sensor component 1314 may include a proximity sensor configured to detect the presence of a nearby object without any physical contact. The sensor component 1314 may also include a light sensor, such as a CMOS or CCD image sensor, for use in imaging applications. In some embodiments, the sensor component 1314 may also include an accelerometer sensor, a gyroscope sensor, a magnetic sensor, a pressure sensor, or a temperature sensor.

The communication component 1316 is configured to facilitate communication, wired or wirelessly, between the device 1300 and other devices. The device 1300 can access a wireless network based on a communication standard, such as WiFi, 2G, or 3G, or a combination thereof. In an exemplary embodiment, the communication component 1316 receives a broadcast signal or broadcast associated information from an external broadcast management system via a broadcast channel. In an exemplary embodiment, the communication component 1316 further includes a near field communication (NFC) module to facilitate short-range communications. For example, the NFC module may be implemented based on a radio frequency identification (RFID) technology, an infrared data association (IrDA) technology, an ultra-wideband (UWB) technology, a BLUETOOTH (BT) technology, and other technologies.

In exemplary embodiments, the device 1300 may be implemented with one or more application specific integrated circuits (ASICs), digital signal processors (DSPs), digital signal processing devices (DSPDs), programmable logic devices (PLDs), field programmable gate arrays (FPGAs), controllers, micro-controllers, microprocessors, or other electronic components, for performing the above described methods.

In exemplary embodiments, there is also provided a non-transitory computer-readable storage medium including instructions, such as included in the memory 1304, executable by the processor 1320 in the device 1300, for performing the above-described methods. For example, the non-transitory computer-readable storage medium may be a ROM, a RAM, a CD-ROM, a magnetic tape, a floppy disc, an optical data storage device, and the like.

One embodiment provides a non-transitory computer readable storage medium having stored therein instructions configured to, when executed by a processor of a mobile terminal, cause the mobile terminal to acquire ambient noise information of ambient noise present during playing of sound. The instructions may be further configured to, when executed by a processor of the mobile device, cause the mobile terminal to adjust volume of the sound based on the acquired ambient noise information.

The methods, devices, and modules described above may be implemented in many different ways and as hardware, software or in different combinations of hardware and software. For example, all or parts of the implementations may be a processing circuitry that includes an instruction processor, such as a central processing unit (CPU), microcontroller, a microprocessor; or application specific integrated circuits (ASICs), digital signal processors (DSPs), digital signal processing devices (DSPDs), programmable logic devices (PLDs), field programmable gate arrays (FPGAs), controllers, micro-controllers, microprocessors, other electronic components; or as circuitry that includes discrete logic or other circuit components, including analog circuit components, digital circuit components or both; or any combination thereof. The circuitry may include discrete interconnected hardware components or may be combined on a single integrated circuit die, distributed among multiple integrated circuit dies, or implemented in a Multiple Chip Module (MCM) of multiple integrated circuit dies in a common package, as examples.

Other embodiments of the disclosure will be apparent to those skilled in the art from consideration of the specification and practice of the disclosures herein. This application is intended to cover any variations, uses, or adaptations of the disclosure following the general principles thereof and including such departures from the present disclosure as come within known or customary practice in the art. It is intended that the specification and examples be considered as exemplary only, with a true scope and spirit of the disclosure being indicated by the following claims.

Reference throughout this specification to “one embodiment,” “an embodiment,” “exemplary embodiment,” or the like in the singular or plural means that one or more particular features, structures, or characteristics described in connection with an embodiment is included in at least one embodiment of the present disclosure. Thus, the appearances of the phrases “in one embodiment” or “in an embodiment,” “in an exemplary embodiment,” or the like in the singular or plural in various places throughout this specification are not necessarily all referring to the same embodiment. Furthermore, the particular features, structures, or characteristics in one or more embodiments may be combined in any suitable manner.

The terminology used in the description of the disclosure herein is for the purpose of describing particular examples only and is not intended to be limiting of the disclosure. As used in the description of the disclosure and the appended claims, the singular forms “a,” “an,” and “the” are intended to include the plural forms as well, unless the context clearly indicates otherwise. Also, as used in the description herein and throughout the claims that follow, the meaning of “in” includes “in” and “on” unless the context clearly dictates otherwise. It will also be understood that the term “and/or” as used herein refers to and encompasses any and all possible combinations of one or more of the associated listed items. It will be further understood that the terms “may include,” “including,” “comprises,” and/or “comprising,” when used in this specification, specify the presence of stated features, operations, elements, and/or components, but do not preclude the presence or addition of one or more other features, operations, elements, components, and/or groups thereof

It will be appreciated that the inventive concept is not limited to the exact construction that has been described above and illustrated in the accompanying drawings, and that various modifications and changes can be made without departing from the scope thereof. It is intended that the scope of the disclosure only be limited by the appended claims.

The above embodiments are only the preferred embodiments of the present disclosure, and are not used to limit the present disclosure. Any modification, equivalent, improvement and the like made within the spirit and principle of the present disclosure should be included within the scope claimed by the present disclosure.

What is claimed is:

1. A method for adjusting volume, comprising:
acquiring, with a device, ambient noise information about ambient noise present during playing of sound; and
adjusting, with the device, volume of the sound based on the acquired ambient noise information.

2. The method of claim 1, wherein acquiring the ambient noise information comprises:
detecting the ambient noise information with a noise capture sensor built into the device; or
receiving the ambient noise information from a noise capture device separate from the device.

3. The method of claim 1, wherein adjusting the volume of the sound based on the acquired ambient noise information comprises:
acquiring an amplitude of the ambient noise from the acquired ambient noise information;
increasing the volume of the sound when the acquired amplitude of the ambient noise is equal to or above a first predetermined threshold; and
decreasing the volume of the sound when the acquired amplitude of the ambient noise is equal to or below a second predetermined threshold.

4. The method of claim 1, wherein adjusting the volume of the sound based on the acquired ambient noise information comprises:
acquiring an amplitude of the ambient noise from the acquired ambient noise information;
increasing the volume of the sound when the acquired amplitude of the ambient noise is equal to or above a first predetermined threshold for a period exceeding a predetermined value; and
decreasing the volume of the sound when the acquired amplitude of the ambient noise is equal to or below a second predetermined threshold for a period exceeding a predetermined value.

5. The method of claim 3, further comprising, before the increasing of the volume of the sound, recording an original volume of the sound; and
wherein the decreasing of the volume of the sound comprises, after the increasing of the volume of the sound, decreasing the volume of the sound to the recorded original volume.

6. The method of claim 1, wherein adjusting the volume of the sound based on the acquired ambient noise information comprises:
acquiring an amplitude of the ambient noise from the acquired ambient noise information;
acquiring a volume adjustment parameter corresponding to the acquired amplitude of the ambient noise; and
adjusting the volume of the sound based on the acquired volume adjustment parameter.

7. The method of claim 1, wherein adjusting the volume of the sound based on the acquired ambient noise information comprises:
when the sound is playing on the device, directly adjusting, with the device, the volume of the sound playing on the device, based on the acquired ambient noise information; and
when the sound is playing on a different device:
generating, with the device, a control instruction configured to adjust the volume of the sound based on the acquired ambient noise information, and
sending the generated control instruction to the different device to trigger the different device to adjust the volume of the sound playing on the different device, based on the acquired ambient noise information.

8. A device for adjusting volume, comprising:
a processor; and
a memory for storing processor-executable instructions;
wherein the processor is configured to:
acquire ambient noise information about ambient noise present during playing of sound; and
adjust volume of the sound based on the acquired ambient noise information.

9. The device of claim 8, wherein the processor is further configured to:
detect the ambient noise information with a noise capture sensor built into the device; or receive the ambient noise information from a noise capture device separate from the device.

10. The device of claim 8, wherein the processor is further configured to:
acquire an amplitude of the ambient noise from the acquired ambient noise information;
increase the volume of the sound when the acquired amplitude of the ambient noise is equal to or above a first predetermined threshold; and
decrease the volume of the sound when the acquired amplitude of the ambient noise is equal to or below a second predetermined threshold.

11. The device of claim 8, wherein the processor is further configured to:
acquire an amplitude of the ambient noise from the acquired ambient noise information;
increase the volume of the sound when the acquired amplitude of the ambient noise is equal to or above a first predetermined threshold for a period exceeding a predetermined value; and
decrease the volume of the sound when the acquired amplitude of the ambient noise is equal to or below a second predetermined threshold for a period exceeding a predetermined value.

12. The device of claim 10, wherein the processor is further configured to:
before increasing the volume of the sound, record an original volume of the sound; and
decrease the volume of the sound to the recorded original volume.

13. The device of claim 8, wherein the processor is further configured to:
acquire an amplitude of the ambient noise from the acquired ambient noise information;
acquire a volume adjustment parameter corresponding to the acquired amplitude of the ambient noise; and
adjust the volume of the sound based on the acquired volume adjustment parameter.

14. The device of claim 8, wherein the processor is further configured to:
when the sound is playing on the device, directly adjust the volume of the sound playing on the device, based on the acquired ambient noise information; and
when the sound is playing on a different device:
generate a control instruction configured to adjust the volume of the sound based on the acquired ambient noise information, and
send the generated control instruction to the different device to trigger the different device to adjust the volume of the sound playing on the different device, based on the acquired ambient noise information.

15. A non-transitory computer-readable storage medium having stored therein instructions configured to, when executed by a processor of a mobile terminal, cause the mobile terminal to:
acquire ambient noise information about ambient noise present during playing of sound; and
adjusting volume of the sound based on the acquired ambient noise information.

16. The non-transitory computer-readable storage medium of claim 15, wherein the instructions are further configured to, when executed by a processor of the mobile terminal, cause the mobile terminal to:
detect the ambient noise information with a noise capture sensor built into the mobile terminal; or
receive the ambient noise information from a noise capture device separate from the mobile terminal.

17. The non-transitory computer-readable storage medium of claim 15, wherein the instructions are further configured to, when executed by a processor of the mobile terminal, cause the mobile terminal to:
acquire an amplitude of the ambient noise from the acquired ambient noise information;
increase the volume of the sound when the acquired amplitude of the ambient noise is equal to or above a first predetermined threshold; and
decrease the volume of the sound when the acquired amplitude of the ambient noise is equal to or below a second predetermined threshold.

18. The non-transitory computer-readable storage medium of claim 16, wherein the instructions are further configured to, when executed by a processor of the mobile terminal, cause the mobile terminal to:
before increasing the volume of the sound, record an original volume of the sound; and
decrease the volume of the sound to the recorded original volume.

19. The non-transitory computer-readable storage medium of claim 15, wherein the instructions are further configured to, when executed by a processor of the mobile terminal, cause the mobile terminal to:
acquire an amplitude of the ambient noise from the acquired ambient noise information;
acquire a volume adjustment parameter corresponding to the acquired amplitude of the ambient noise; and
adjust the volume of the sound based on the acquired volume adjustment parameter.

20. The non-transitory computer-readable storage medium of claim 15, wherein the instructions are further configured to, when executed by a processor of the mobile terminal, cause the mobile terminal to:
when the sound is playing on the mobile terminal, directly adjust the volume of the sound playing on the mobile terminal, based on the acquired ambient noise information; and
when the sound is playing on a different terminal:
generate a control instruction configured to adjust the volume of the sound based on the acquired ambient noise information, and
send the generated control instruction to the different terminal to trigger the different terminal to adjust the volume of the sound playing on the different terminal, based on the acquired ambient noise information.
